(19) United States
(12) Patent Application Publication
(10) Pub. No.: US 2013/0074912 A1
(43) Pub. Date: Mar. 28, 2013

(54) BAND STRUCTURE ENGINEERING FOR IMPROVED EFFICIENCY OF CDTE BASED PHOTOVOLTAICS

(71) Applicant: RoseStreet Labs, LLC, Phoenix, AZ (US)

(72) Inventors: Wladyslaw Walukiewicz, Kensington, CA (US); Lothar A. Reichertz, Berkeley, CA (US)

(73) Assignee: ROSESTREET LABS, LLC, Phoenix, AZ (US)

(21) Appl. No.: 13/625,592

(22) Filed: Sep. 24, 2012

Related U.S. Application Data
(60) Provisional application No. 61/538,057, filed on Sep. 22, 2011.

(51) Int. Cl. H01L 31/0296; H01L 31/18; H01L 31/073

(52) U.S. Cl. 136/255; 136/260; 438/94; 257/E31.016

(57) ABSTRACT

Disclosed is a solar cell or component thereof that includes a p-type thin film solar light absorbing layer having one or more compositions of group II-VI alloys described as CdTeₓM₁₋ₓ, where M is S, Se or O. An n-type thin-film transparent window layer comprising CdS is provided adjacent to the CdTeₓMᵢ₋ₓ p-type thin film solar light absorbing layer such that a p-n junction formed between the layers.

### CROSS REFERENCE To RELATED APPLICATION(S)

This application claims priority to U.S. Provisional Patent Application No. 61/538,057 filed Sep. 22, 2011, the entire disclosure of which is incorporated herein by reference.

### STATEMENT OF GOVERNMENTAL INTEREST

The invention described and claimed herein was made in part utilizing funds supplied by the U.S. Department of Energy under Contract No. DE-AC02-05CH11231. The government has certain rights in this invention.

### FIELD OF THE INVENTION

This disclosure relates to solar cells, and more particularly to CdTe based photovoltaic cells.

### BACKGROUND OF THE INVENTION

Solar or photovoltaic cells are semiconductor devices which directly convert radiant energy of sunlight into electrical energy. Conversion of sunlight into electrical energy involves three major processes: absorption of sunlight into the semiconductor material; generation and separation of positive and negative charges creating a voltage in the solar cell; and collection and transfer of the electrical charges through terminals connected to the semiconductor material.

Current traditional solar cells based on single semiconductor material have a practical efficiency limit of approximately 25%. A primary reason for this limit is that no one material has been found that can perfectly match the broad ranges of solar radiation, which has a usable energy in the photon range of approximately 0.4 to 4 eV. Light with energy below the bandgap of the semiconductor will not be absorbed and converted to electrical power. Light with energy above the bandgap will be absorbed, but electron-hole pairs that are created quickly lose their excess energy above the bandgap in the form of heat. Thus, this energy is not available for conversion to electrical power.

One important consideration in solar cell applications is the cost of component materials and fabrication of solar panels. Most of currently produced solar cells use silicon (Si) semiconductor, a widely available and abundant material. The main disadvantage of silicon is its low absorption coefficient of solar photons. This requires use of relatively thick layers to fully absorb solar light. This in turn requires using wafers cut from bulk silicon crystals that are relatively expensive to produce.

A significant cost reduction can be achieved by switching from Si, which is a low absorption indirect gap semiconductor, to direct band gap semiconductors with orders of magnitude higher solar light absorption coefficients. In these materials, only thin films on the order of microns are required to fully absorb solar photons.

The currently most successful thin film technologies are based on Cadmium Telluride (CdTe) and Copper Indium Gallium Selenium (CuInGaSe2) materials. The basic structure of a typical CdTe solar cell is shown in FIG. 1. In both cases, the pn junction is formed between p-type CdTe or CuInGaSe2 absorbing layer and n-type window layer. A variety of wide-gap n-type semiconductors can be used as window layers. In the case of a CdTe absorbing layer, the best windows are often made of thin films of n-type CdS. Record power conversion efficiencies of about 16% were achieved on n-CdS/p-CdTe solar cell structures. The efficiency was obtained with the open circuit voltage of 0.84 V, short circuit current of 25 mA/cm² and fill factor of 75%. (ref. Appl. Phys. Lett. 62 (22), 31 May 1993).

Highly mismatched alloys (HMAs) is a new class of semiconductor materials that are formed of materials with distinctly different electro negativities and atom size. The electronic properties of these materials, such as band gap, conduction, and the valence band offset can be controlled by the alloy composition. A large number of HMAs have been synthesized and studied. The electronic properties are well described by the band anti-crossing (BAC) model.

### SUMMARY

Compositions of group II-VI alloys are provided to form a solar light absorber which, with appropriate choice of transparent window, will form a solar cell with optimized solar power conversion efficiency. In one or more embodiments, an alloy of CdSTe, CdSeTe or CdOTe is formed on a CdS window/emitter layer. The alloy composition is selected to maximize short circuit current without substantially reducing the open circuit voltage. Theoretical modeling shows up to 50% increase of the solar power conversion efficiencies compared with current technologies.

In accordance with one or more embodiments, the invention provides a solar cell or component thereof that includes a p-type thin film solar light absorbing layer comprising one or more compositions of group II-VI alloys described as CdTeₓM₁₋ₓ, where M is S, Se or O. An n-type thin-film transparent window/emitter layer comprising CdS is provided adjacent to the CdTeₓM₁₋ₓ p-type thin film solar light absorbing layer such that a p-n junction formed between the layers.

### BRIEF DESCRIPTION OF THE DRAWINGS

The above-mentioned features and objects of the present disclosure will become more apparent with reference to the following description taken in conjunction with the accompanying drawings wherein like reference numerals denote like elements and in which:

FIG. 1 is a block diagram representation illustrating the structure of a typical CdTe based solar cell.

FIG. 2 is a schematic diagram illustrating hetero junction formation in a CdTe solar cell.

FIG. 3 shows a calculated band diagram for a CdTeₓS₁₋ₓ alloy.

FIG. 4 shows a calculated band diagram for a CdTe_{y}Se_{1-y} alloy.

FIG. 5 shows a calculated band diagram for a CdTe_{z}O_{1-z} alloy.

FIG. 6 is a chart illustrating standard AM1.5 G solar spectrum and positions of band gap energies for CdTe and CdTe_{0.65}Se_{0.35}.

FIG. 7 is a chart illustrating maximum possible current (100% quantum efficiency) under standard AM1.5G solar examination as a function of energy gap.

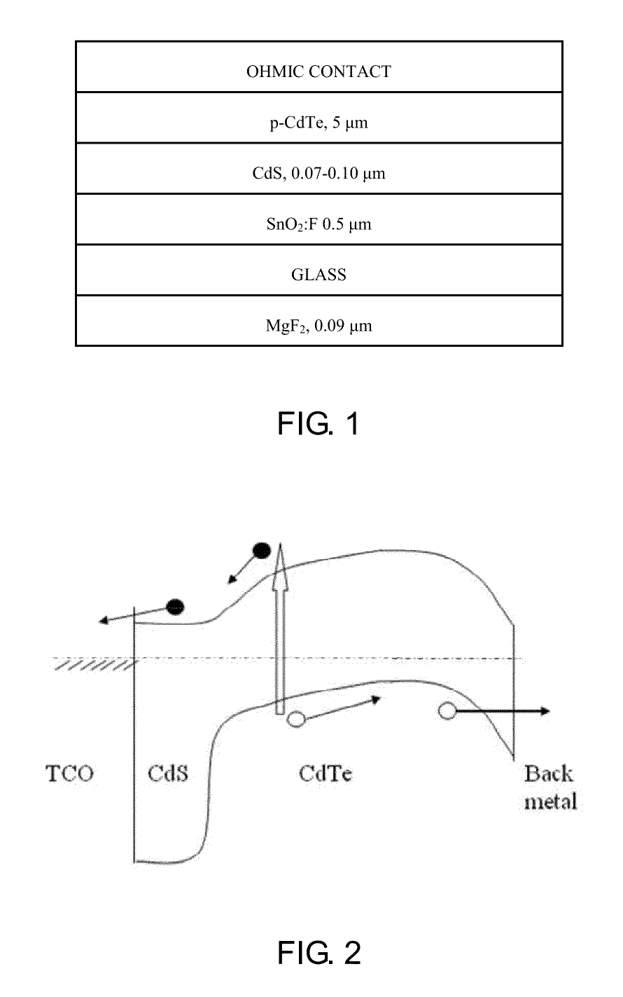

### DETAILED DESCRIPTION

In accordance with an embodiment of the invention, compositions of group II-VI alloys are provided to form a solar light absorber which, with appropriate choice of transparent window, forms a solar cell with optimized solar power conversion efficiency. In one or more embodiments, an alloy of CdSTe, CdSeTe or CdOTe is formed on a CdS window. The alloy composition is selected to maximize short circuit current without reducing the open circuit voltage. Theoretical modeling shows up to 50% increase of the solar power conversion efficiencies compared with current technologies.

In an embodiment, a solar cell includes an active layer that consists of a thin film of n-type CdS followed by few-micron-thick p-type CdTe. The CdS film acts as a window, but also plays an important role as an electron emitter. As is shown in FIG. 2 a hetero-pn junction is formed between CdS and CdTe films. The light is absorbed in the p-type CdTe. The photoexcited carriers are separated in the junction with electrons moving to CdS and holes drawn to CdTe. The short circuit current is given by the flux of absorbed solar photons with energy large than the band gap of CdTe (1.5 eV) whereas the open circuit voltage is determined by the Fermi energy difference between conduction band of CdS and the valence band of CdTe. From the known band offsets this energy is estimated to be about 1.2 eV. This explains the value of the open circuit voltage of only about 0.85 V which is much smaller than the more than 1 V expected for the CdTe absorber with the band gap of 1.5 eV.

In accordance with an embodiment of the present invention, the electronic band structure of the p-type absorber layer is designed to compensate for the mismatch between short circuit current and the open circuit voltage in the CdS/CdTe solar cell. We discovered CdTe based semiconductor alloys whose energy gap can be reduced to absorb more solar light without reducing the open circuit voltage.

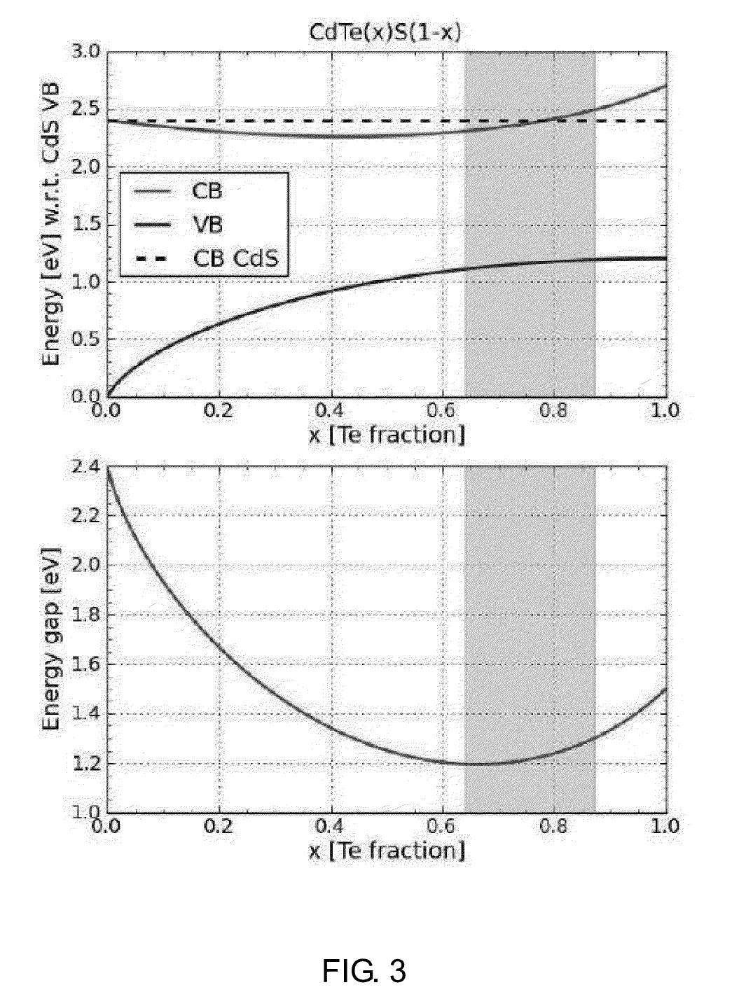

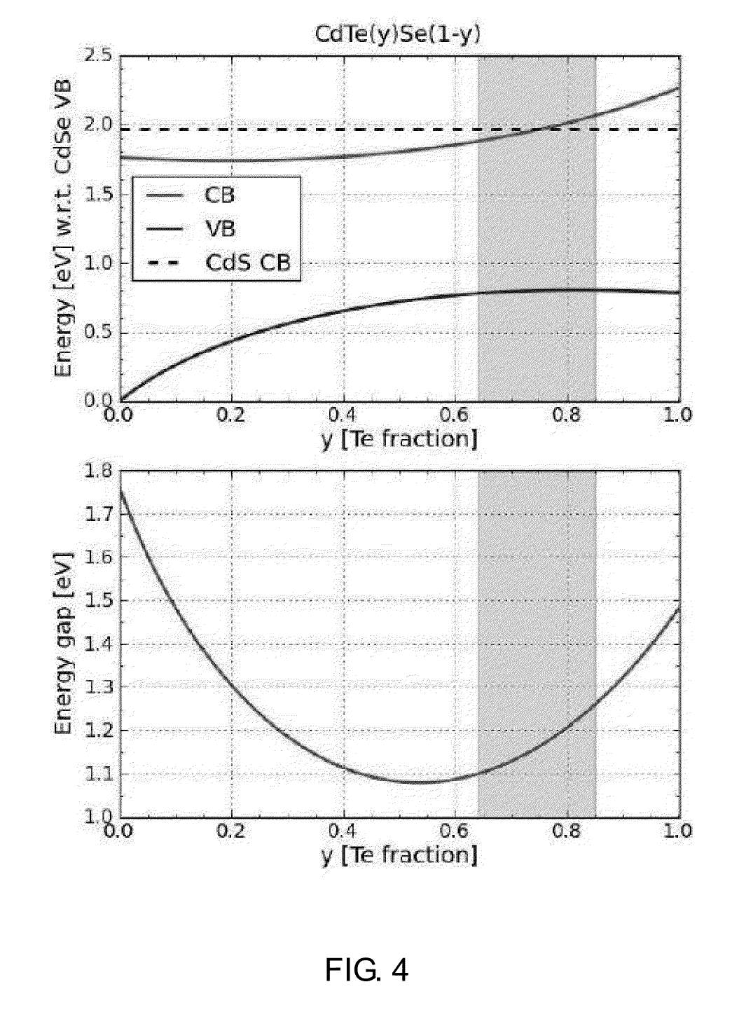

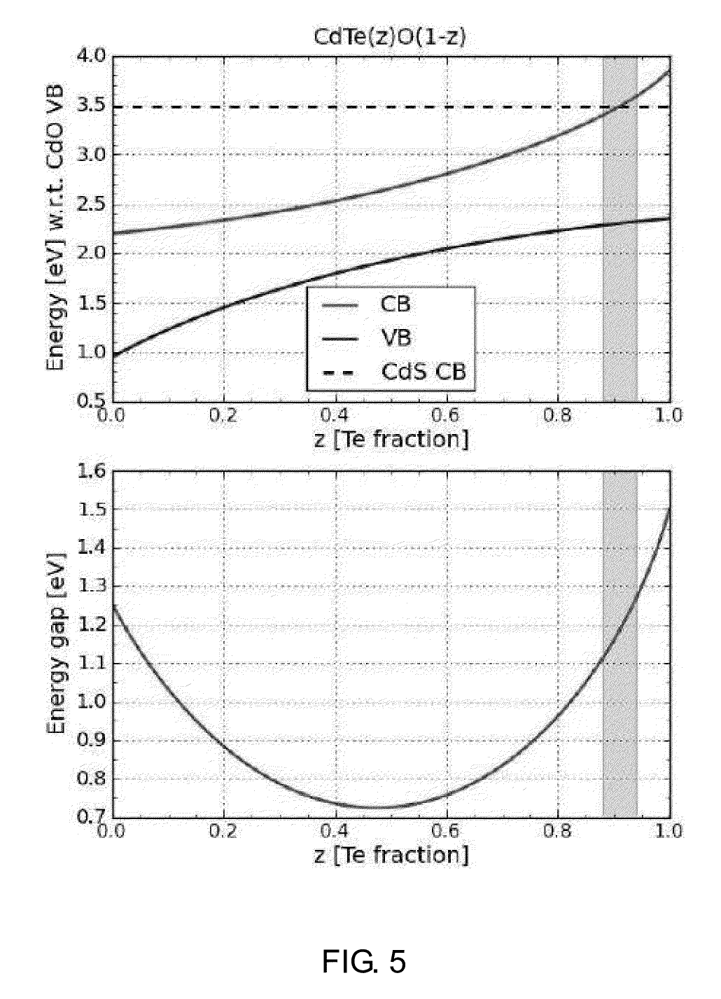

Examples of such alloys are shown in FIGS. 3 to 5. FIG. 3 shows a calculated band diagram for a CdTeₓS₁₋ₓ alloy. FIG. 4 shows a calculated band diagram for a CdTe_{y}Se_{1-y} alloy. FIG. 5 shows a calculated band diagram for a CdTe_{z}O_{1-z} alloy. In each of FIGS. 3-5, the shaded area marks the composition range for optimum alignment with the CdS conduction band.

The main feature of the alloys illustrated in FIGS. 3-5 is that replacement of Te atoms with smaller more electronegative atoms M (where M is S, Se or O) leads to a downward shift of the conduction band edge in resulting CdTeₓM₁₋ₓ alloys. The performance of this CdTeₓM₁₋ₓ solar cell is optimized when the conduction band edge of the CdTeₓM₁₋ₓ band absorber is approximately (within a 0.1 eV margin) aligned with the conduction band edge of CdS. As is shown in FIGS. 3 to 5, this happens for 0.78<x<0.87 in CdTeₓS₁₋ₓ for 0.74<y<0.85 in CdTe_{y}Se_{1-y} and for 0.90<z<0.94 in CdTe_{z}O_{1-z}. The band gaps of the corresponding alloys range from 1.1 to 1.3 eV. Also, since for the alloy compositions close to CdTe the valence band edge energy does not vary significantly with composition, therefore the Fermi energy difference between n-type CdS window and p-type CdTeₓM₁₋ₓ absorber and thus also the open circuit voltage in n-CdS/p-CdTeₓM₁₋ₓ will be the same as in the case of currently used n-CdS/p-CdTe junction.

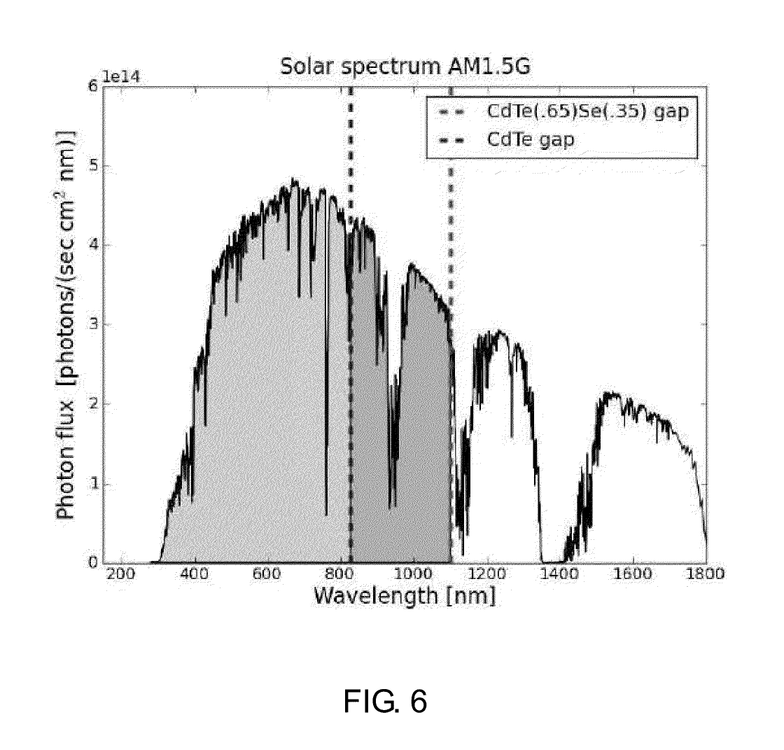

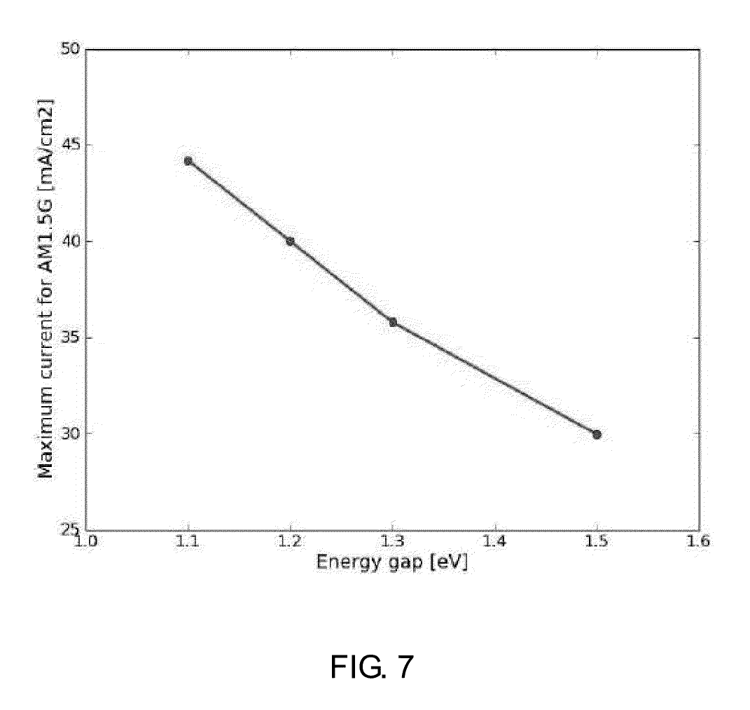

FIG. 6 shows a chart illustrating standard AM1.5 G solar spectrum and positions of band gap energies for CdTe and CdTe_{0.65}Se_{0.35}. The orange shaded area marks the additional photon flux captured due to the reduced band gap energy of CdTe_{0.65}Se_{0.35}. FIG. 7 is a chart illustrating maximum possible current (100% quantum efficiency) under standard AM1.5G solar examination as a function of energy gap. The efficiency improvement discussed above will occur because, as is illustrated in FIGS. 6 and 7, CdTeₓM₁₋ₓ with a smaller gap of 1.1 to 1.3 eV will absorb a larger part of the solar spectrum than CdTe with a band gap of 1.5 eV. A large, up to 50% efficiency increase in the optimum cases of CdTeₓS₁₋ₓ with x˜0.65 and CdTe_{y}Se_{1-y} with y˜0.65 can be expected. This indicates that the current record cell efficiency of 16% for CdS/CdTe cells could increase to 24% with the use of an optimized absorber.

In addition, the CdTeₓM₁₋ₓ absorber layer can be of uniform composition across the layer thickness or can be compositionally graded from the composition that matches the conduction band edges at the interface of the CdS window and the CdTeₓM₁₋ₓ absorber to CdTe close to the surface. The grading will improve the collection efficiency of photo generated electrons.

In an embodiment, the CdTeₓM_{1 x} solar light absorbing layer is p-type doped and has a thickness of 4 to 8 microns, while the CdS thin-film transparent window/emitter layer is abut 0.05 to 0.1 micron thick. The CdS thin-film transparent window/emitter layer and the CdTeₓM₁₋ₓ solar light absorbing layer can be formed by pulsed laser deposition and/or sputtering. In an embodiment, both pulsed laser deposition and sputtering are used. Pulsed laser deposition is a thin film physical vapor deposition (PVD) technique in which a high powered pulsed laser beam is focused inside a vacuum chamber to strike a target of the material that is to be deposited. This material is vaporized from the target which deposits it as a thin film on a substrate. This process can occur in ultra high vacuum or in the presence of a background gas, such as oxygen. Sputtering is another PVD technique, and involves ejecting material from a target that is a source onto a substrate. Other PVD techniques may be used to form the thin-film transparent window/emitter layer and/or the CdTeₓM₁₋ₓ solar light absorbing layer without departing from the spirit and scope of the invention.

What is claimed is:

1. A solar cell or component thereof, comprising:
a p-type thin film solar light absorbing layer comprising one or more compositions of group II-VI alloys described as CdTeₓM₁₋ₓ, where M is S, Se or O;
an n-type thin-film transparent window layer comprising CdS;
a p-n junction formed between said CdTeₓM₁₋ₓ p-type solar light absorbing layer and said CdS n-type thin-film transparent window layer.

2. The solar cell or component thereof according to claim 1, wherein said one or more compositions of group II-VI alloys comprises a CdTeₓS₁₋ₓ alloy.

3. The solar cell or component thereof according to claim 1, wherein said one or more compositions of group II-VI alloys comprises a CdTe_{y}Se_{1-y} alloy.

4. The solar cell or component thereof according to claim 1, wherein said one or more compositions of group II-VI alloys comprises a CdTe_{z}O_{1-z} alloy.

5. The solar cell or component thereof according to claim 1, wherein a conduction band edge of the CdTeₓM₁₋ₓ absorbing layer is in approximate alignment with a conduction band edge of the CdS n-type thin-film transparent window layer.

6. The solar cell or component thereof according to claim 5, wherein said approximate alignment comprises alignment within a 0.1 eV margin.

7. The solar cell or component thereof according to claim 1, wherein said CdS n-type thin-film transparent window layer comprises CdSTe.

8. The solar cell or component thereof according to claim 1, wherein said CdS n-type thin-film transparent window layer comprises CdSeTe.

9. The solar cell or component thereof according to claim 1, wherein said CdS n-type thin-film transparent window layer comprises CdOTe.

10. The solar cell or component thereof according to claim 1, wherein an alloy composition of said CdS n-type thin-film transparent window layer is selected to maximize short circuit current without reducing open circuit voltage.

11. The solar cell or component thereof according to claim 1, characterized by producing an open circuit voltage of about 0.85 volts.

12. The solar cell or component thereof according to claim 1, wherein the CdTeₓM₁₋ₓ p-type thin film solar light absorbing layer is of uniform composition across its layer thickness.

13. The solar cell or component thereof according to claim 1, wherein said CdTeₓM₁₋ₓ p-type thin film solar light absorbing layer is compositionally graded from a composition that matches the conduction band edges at an interface of the CdS window layer and the CdTeₓM₁₋ₓ light absorbing layer to CdTe close to a surface of said light absorbing layer.

14. A method of forming a solar cell or component thereof, comprising:
arranging a p-type thin film solar light absorbing layer comprising one or more compositions of group II-VI alloys described as CdTeₓM₁₋ₓ, where M is S, Se or O, such that the solar light absorbing layer is adjacent to an n-type thin-film transparent window layer comprising CdS, such that a p-n junction formed between said CdTeₓM₁₋ₓ p-type solar light absorbing layer and said CdS n-type thin-film transparent window layer.

15. The method of forming a solar cell or component thereof in accordance with claim 14, wherein said arranging step comprises a physical vapor deposition step.

16. The method of forming a solar cell or component thereof in accordance with claim 15, wherein said arranging physical vapor deposition step comprises pulsed laser deposition.

17. The method of forming a solar cell or component thereof in accordance with claim 15, wherein said arranging physical vapor deposition step comprises sputtering.

18. The method of forming a solar cell or component thereof according to claim 14, wherein said one or more compositions of group II-VI alloys comprises a CdTeₓS₁₋ₓ alloy.

19. The method of forming a solar cell or component thereof according to claim 14, wherein said one or more compositions of group II-VI alloys comprises a CdTe_{y}Se_{1-y} alloy.

20. The method of forming a solar cell or component thereof according to claim 14, wherein said one or more compositions of group II-VI alloys comprises a CdTe_{z}O_{1-z} alloy.

21. The method of forming a solar cell or component thereof according to claim 14, wherein said CdS n-type thin-film transparent window layer comprises CdSTe.

22. The method of forming a solar cell or component thereof according to claim 14, wherein said CdS n-type thin-film transparent window layer comprises CdSeTe.

23. The method of forming a solar cell or component thereof according to claim 14, wherein said CdS n-type thin-film transparent window layer comprises CdOTe.

24. The method of forming a solar cell or component thereof according to claim 14, further comprising selecting an alloy composition to maximize short circuit current without substantially reducing open circuit voltage.

25. The method of forming a solar cell or component thereof according to claim 14, further comprising selecting a composition of said CdTeₓM₁₋ₓ absorbing layer and a composition of said CdS n-type thin-film transparent window layer such that a conduction band edge of the CdTeₓM₁₋ₓ absorbing layer is in approximate alignment with a conduction band edge of the CdS n-type thin-film transparent window layer.
